(19) United States
(12) Patent Application Publication
(10) Pub. No.: US 2025/0311383 A1
(43) Pub. Date: Oct. 2, 2025

(54) Source-Drain Isolation for Complementary Field Effect Transistors

(71) Applicant: Applied Materials, Inc., Santa Clara, CA (US)

(72) Inventors: Gregory COSTRINI, Flanders, NJ (US); Sai Hooi YEONG, Cupertino, CA (US); Ashish PAL, San Ramon, CA (US); El Mehdi BAZIZI, San Jose, CA (US); Benjamin COLOMBEAU, San Jose, CA (US); Balasubramanian PRANATHARTHIHARAN, San Jose, CA (US)

(21) Appl. No.: 18/617,027

(22) Filed: Mar. 26, 2024

(51) Int. Cl. H01L 21/8238

(52) U.S. Cl. CPC H10D 84/038; H10D 84/0186; H10D 84/0188

(57) ABSTRACT

A method for isolating a source-drain of a complementary field-effect-transistor (CFET) stack incorporates a bottom-up fill process to form an isolation layer between vertical structures. The method may include forming an opening to expose a material of a bottom stack of a CFET structure that includes a top stack positioned vertically over the bottom stack where the opening has an aspect ratio of width to depth of approximately 15 or greater. A source-drain isolation (SDI) layer is then formed on the material of the bottom stacks of the CFET structure using a bottom-up fill process that includes depositing an SDI material and etching of the SDI material to achieve formation of the SDI layer. The SDI layer is positioned to electrically isolate source-drains of the bottom stack from source-drains of the top stack.

### FIELD

Embodiments of the present principles generally relate to semiconductor processing of semiconductor substrates.

### BACKGROUND

Complementary metal-oxide-semiconductor (CMOS) transistors are continuously evolving or “scaling” to provide higher performance in smaller packages. The planar CMOS transistors have given way to the fin field-effect-transistor (FinFET) which has been superseded by the gate-all-around (GAA) transistor. The GAA transistor may include a PMOS transistor stack beside an NMOS transistor stack. However, the side-by-side configuration of the GAA transistor takes up valuable area on a device. In order to reduce the area of the GAA transistor, monolithic integrated complementary field-effect-transistors (CFETs) are being considered. Monolithic integrated CFETs may have an NMOS transistor stack positioned over a PMOS transistor stack or a PMOS transistor stack positioned over an NMOS transistor stack. The vertical stacking of the monolithic integrated CFETs reduces the area of the transistor substantially. However, the inventors have observed that the actual manufacturing of the monolithic integrated CFETs leads to process difficulties as the aspect ratio of the vertical stack is very high.

Accordingly, the inventors have provided improved methods for CFET manufacturing.

### SUMMARY

Methods for isolating a source-drain of a CFET structure are provided herein.

In some embodiments, a method for isolating a source-drain of a complementary field-effect-transistor (CFET) structure may comprise forming an opening to access a bottom stack of a CFET structure that also includes a top stack positioned vertically over the bottom stack, wherein the opening has an aspect ratio of width to depth of approximately 15 or greater and forming a source-drain isolation (SDI) layer on a material of the bottom stack of the CFET structure using a bottom-up fill process that includes depositing of an SDI material and etching of the SDI material to achieve formation of the SDI layer, wherein the SDI layer is positioned to electrically isolate source-drains of the bottom stack from source-drains of the top stack.

In some embodiments, the method may further include a material of the bottom stack of the CFET structure that is a metal contact material or a dummy contact material and where the SDI layer is formed on the metal contact material or the dummy contact material, a bottom stack that is a P-type metal-oxide-semiconductor (MOS) stack and a top stack that is an N-type MOS stack or where the bottom stack is an N-type MOS stack and the top stack is a P-type MOS stack, formation of an SDI layer that is accomplished in situ in a chamber that performs deposition and etching of the SDI material, an SDI layer that is formed using a plasma enhanced chemical vapor deposition (PECVD) process or a plasma enhanced atomic level deposition (PEALD) process, an SDI layer that is formed of silicon dioxide material, silicon nitride material, silicon oxynitride material, silicon oxycarbide material, or aluminum oxide material, a second source-drain of the top stack that is formed on the SDI layer using an epitaxial deposition process, a thickness variability of the SDI layer that is approximately 10% of a target thickness of the SDI layer, an opening that has a depth of approximately 400 nm, a thickness of the SDI layer that is approximately 5 nm to approximately 50 nm, etching of an SDI material that includes using chlorine-based gases or fluorine-based gases to etch deposition material from sidewalls of the opening, a number of cycles of depositing SDI material and etching SDI material that is adjusted based on an aspect ratio of the opening, and/or multiple cycles of depositing SDI material that are performed before multiple cycles of etching SDI materials are performed.

In some embodiments, a method for isolating a source-drain of a complementary field-effect-transistor (CFET) structure that may comprise forming an opening to access a first source-drain of a bottom stack of a CFET structure that also includes a top stack positioned vertically over the bottom stack where the opening has an aspect ratio of width to depth of approximately 15 or greater, forming a metal contact layer or a dummy contact layer on the first source-drain of the bottom stack of the CFET structure, and forming a source-drain isolation (SDI) layer on the metal contact layer or the dummy contact layer using a bottom-up fill process that includes depositing of an SDI material and etching of the SDI material to achieve formation of the SDI layer where the SDI layer electrically isolates source-drains of the bottom stack from source-drains of the top stack where the SDI layer is formed using a plasma enhanced chemical vapor deposition (PECVD) process or a plasma enhanced atomic level deposition (PEALD) process and where formation of the SDI layer is accomplished in situ in a chamber that performs deposition and etching of the SDI material.

In some embodiments, the method further includes a bottom stack that is a P-type metal-oxide-semiconductor (MOS) stack and a top stack that is an N-type MOS stack or where the bottom stack is an N-type MOS stack and the top stack is a P-type MOS stack, an SDI layer that is formed of silicon dioxide material, silicon nitride material, silicon oxynitride, silicon oxycarbide, or aluminum oxide, a second source-drain of the top stack that is formed on the SDI layer using an epitaxial deposition process, a thickness variability of the SDI layer that is approximately 10% of a target thickness of the SDI layer, and/or a thickness of the SDI layer that is approximately 5 nm to approximately 50 nm.

In some embodiments, a non-transitory, computer readable medium having instructions stored thereon that, when executed, cause a method for isolating a source-drain of a complementary field-effect-transistor (CFET) structure to be performed, the method may comprise forming an opening to access a bottom stack of a CFET structure that also includes a top stack positioned vertically over the bottom stack, wherein the opening has an aspect ratio of width to depth of approximately 15 or greater and forming a source-drain isolation (SDI) layer on a material of the bottom stack of the CFET structure using a bottom-up fill process that includes depositing of an SDI material and etching of the SDI material to achieve formation of the SDI layer, wherein the SDI layer is positioned to electrically isolate source-drains of the bottom stack from source-drains of the top stack.

Other and further embodiments are disclosed below.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 depicts a cross-sectional view of simplified representation of a complementary field-effect-transistor (CFET) in accordance with some embodiments of the present principles.

FIG. 2 is a method of forming source-drain isolation (SDI) layers of a CFET in accordance with some embodiments of the present principles.

FIG. 3 depicts an isometric cutaway view of a CFET structure being formed in accordance with some embodiments of the present principles.

FIG. 4 depicts an isometric cutaway view of openings being formed to expose material of bottom stacks of a CFET structure in accordance with some embodiments of the present principles.

FIG. 5 depicts an isometric cutaway view of optional metal or dummy contacts being formed on source-drains of bottom stacks of a CFET structure in accordance with some embodiments of the present principles.

FIG. 6 depicts an isometric cutaway view of SDI layers being formed on material of bottom stacks of a CFET structure in accordance with some embodiments of the present principles.

FIG. 7 depicts an isometric cutaway view of source-drains of top stacks of a CFET structure being formed on SDI layers in accordance with some embodiments of the present principles.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

The methods provide improved processes for forming an isolating layer for source-drains in vertical stacks of a complementary field-effect-transistor (CFET) structure. The present principles enable the device isolation for source-drain contact formation that substantially increases process tolerances to meet the demanding requirements of manufacturing vertical CFET structures. The techniques overcome the shortcomings of traditional gapfill and etch-back processes when used with high aspect ratio structures, allowing efficient manufacturing of CFETs to exacting tolerances. The present techniques significantly reduce the isolating layer thickness variability, the number of processes to form the isolation layer, and the cost of the formation of the isolation layer.

The CFET structure is a recently developed architecture where an N-P device is separated vertically instead of horizontally like a gate-all-around (GAA) device. To enable stacking GAA devices vertically, a method for isolating the devices is required at several points in the process. In particular, a process sequence is used to isolate a bottom device's (e.g., PMOS stack or NMOS stack) and a top device's (e.g., NMOS stack or PMOS stack) source-drain trench contacts. For a quasi-planar GAA structure, the bottom and top device of the CFET structure would be placed laterally and, as such, lithographically separated and isolated. However, because of the vertical stacking of the CFET structure, the CFET requires a process sequence for the formation of the isolation that is compatible with high aspect ratios. Traditional processes use full gapfill to form isolation material which is then planarized using a chemical mechanical polish (CMP) and recessed with etch-back processes to dramatically thin down the gapfill and form the isolation. The inventors have found, however, that because most of the gapfill is removed due to the high aspect ratio (HAR) nature of the vertical stack, tight tolerances on the thickness of the isolation layer cannot be achieved with traditional GAA processes.

The present methods enable device isolation for source-drain contacts that provide substantial process tolerance improvement and cost savings to meet the requirements of the CFET structure. The formation of the N-P device isolation, referred to herein as source-drain isolation (SDI), on the bottom device source-drain contact, leaves the top device exposed for source-drain epitaxy. The tolerance of the proposed process is substantially improved over the traditional approaches since the total deposition height, from the bottom up, is a fraction of the total gate height which would have been gapfilled with traditional approaches. As a result, the total process tolerance is a fraction of the traditional process approaches using gapfill processes. To accomplish the improved performance, in brief, a bottom-up deposition process is used in which the dielectric materials for an SDI layer are deposited using a deposition-etch-deposition process, in situ, in a single chamber.

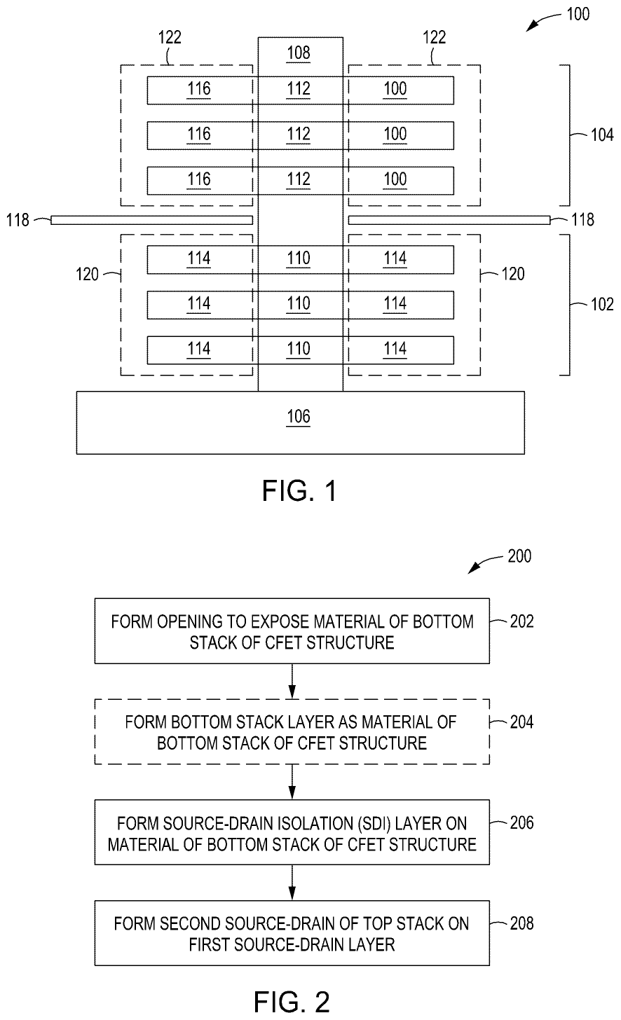

FIG. 1 depicts a cross-sectional view of a simplified representation of a single CFET structure 100. The CFET structure 100 with a gate 108 is formed on a work substrate 106 and the like to isolate the CFET structure 100 from other structures. A bottom stack 102 includes nanosheets with channels 110 and source-drains 114. In some embodiments, the bottom stack 102 may form a P-type CMOS structure. In some embodiments, the bottom stack 102 may form an N-type CMOS structure. A top stack 104 includes nanosheets with channels 112 and source-drains 116. In some embodiments, the top stack 104 may form an N-type CMOS structure. In some embodiments, the top stack 104 may form a P-type CMOS structure. During manufacturing, many of the CFET structures may be formed next to each other to create monolithic integrated CFETs with more than one CFET structure 100. As part of the manufacturing process, the source-drains 114 of the bottom stack 102 may be joined together to form unitary bottom stack source-drains 120. Similarly, the source-drains 116 of the top stack 104 may be joined together to form unitary top stack source-drains 122. As the CFET structure 100 is a vertical structure, the unitary top stack source-drains 122 are constructed directly over the unitary bottom stack source-drains 120. To electrically isolate the unitary bottom stack source-drains 120 and the unitary top stack source-drains 122, an isolation layer or source-drain isolation (SDI) layer 118 is formed in between. The vertical nature of the CFET structure 100 presents manufacturing difficulties that must be overcome to successfully form the CFET structure 100. The present methods, as discussed below, provide technical solutions to manufacturing challenges such as, but not limited to, high aspect ratio processes and the like when forming SDI layers while enabling tight process tolerances.

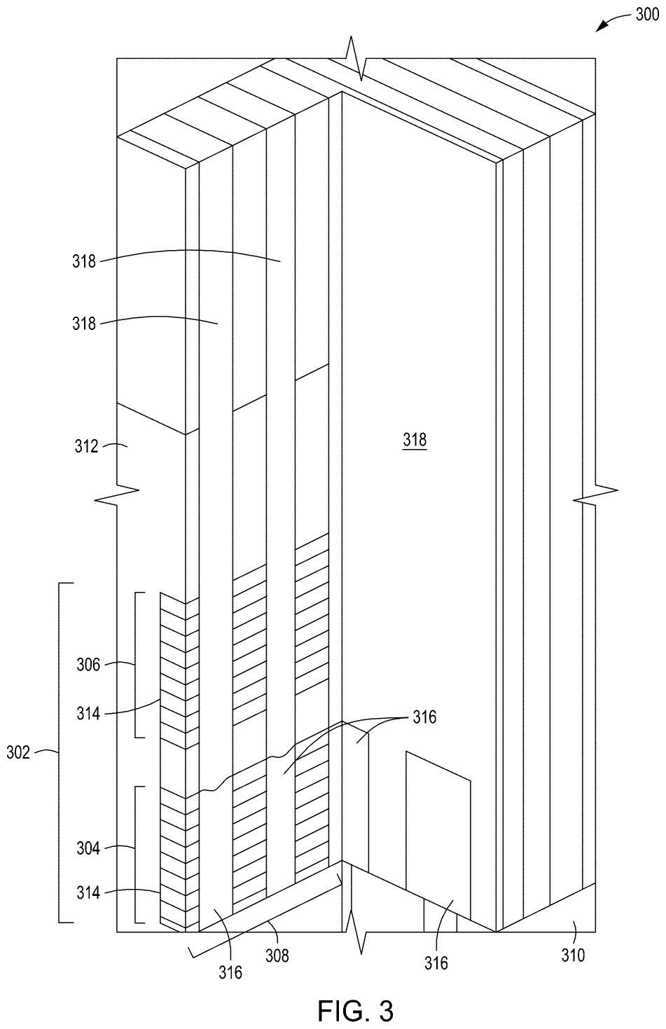

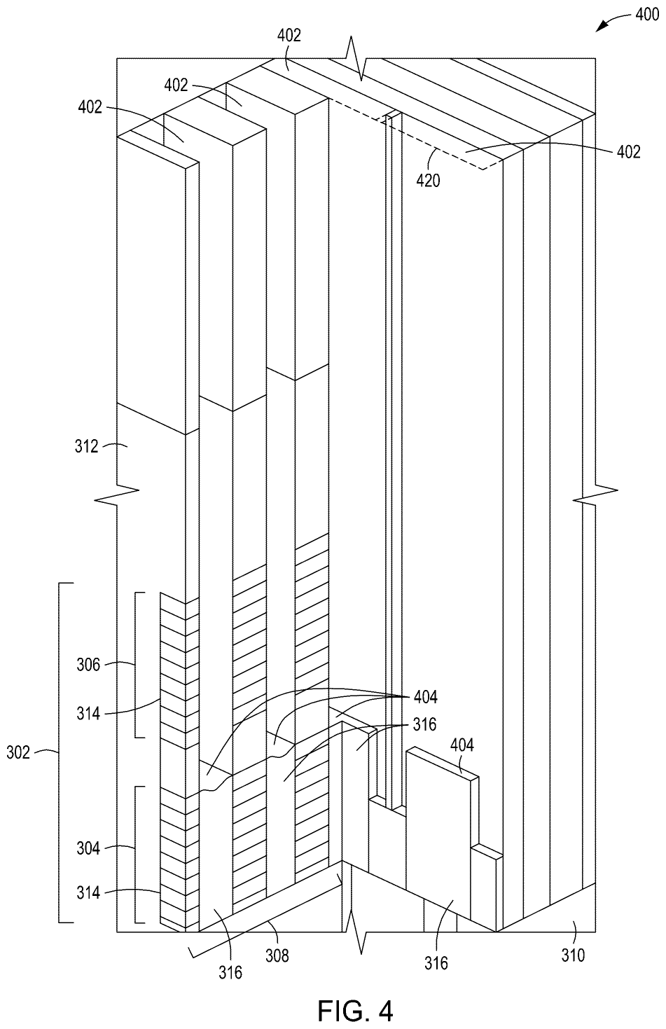

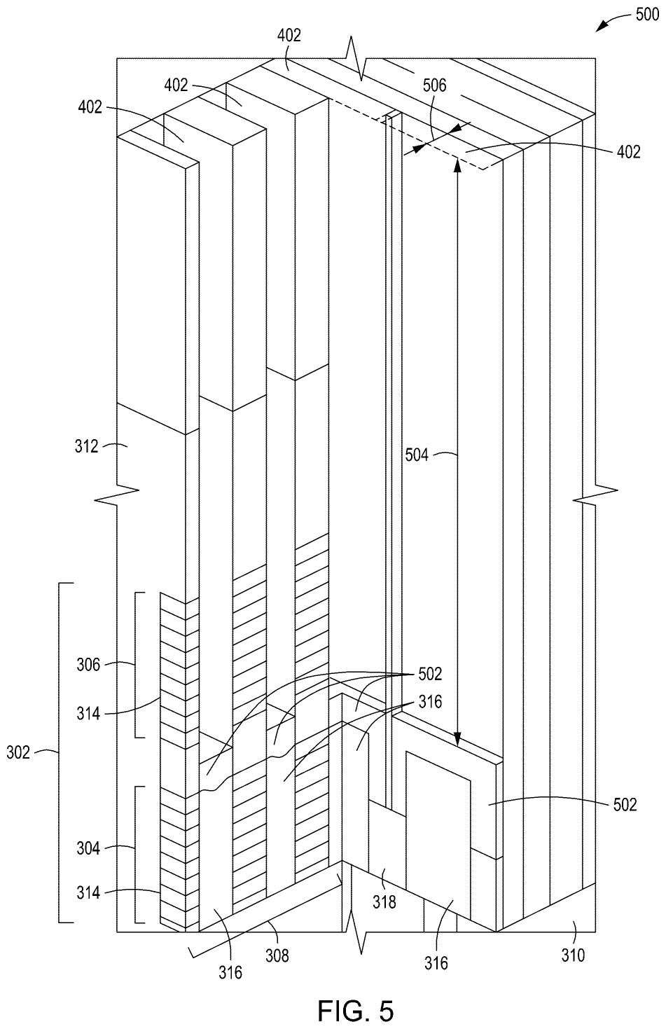

FIG. 2 is a method 200 for isolating source-drains of CFET structures 302 as depicted in a view 300 of FIG. 3. References to additional isometric cutaway views of FIGS. 4-7 will also be made in the discussion of the method 200. The examples used in the depiction of the method 200 are not meant to be limiting in the techniques of the formation of the source-drain isolation (SDI) layer. For the sake of brevity, in some embodiments, the examples include formation of a material of a bottom stack such as a bottom stack layer that may be a metal or dummy contact layer on which the SDI layer is formed. However, the SDI layer may be formed on any material of the bottom stack at the bottom of the openings. The view 300 depicts a portion of multiple CFET structures 308 formed on a substrate 310. The CFET structures 302 include bottom stacks 304 and top stacks 306. The bottom stacks 304 and the top stacks 306 have nanosheets 314 and dummy gates 312 formed in prior processes. In the examples, which are not meant to be limiting, the first source-drains 316 of the bottom stacks 304 and an interlayer dielectric fill 318 have also been formed in prior processes. In block 202 of method 200, openings 402 are formed (e.g., portions of the interlayer dielectric fill 318 are removed, dashed box 420 indicates the dimensional boundaries of an example opening) to access portions 404 of material of the bottom stacks 304 such as, for example, the first source-drains 316 of the bottom stacks 304 of the CFET structures 302 as depicted in a view 400 of FIG. 4. In some embodiments, the accessed material may be previously formed layers of the bottoms stacks 304 such as contacts and the like. In some embodiments, the openings 402 may have a height (or depth, see, e.g., heights 504 of FIG. 5) of approximately 400 nm.

In optional block 204, metal or dummy contact layers 502 or other material layers of the bottom stacks 304 may be formed on the first source-drains 316 as depicted in a view 500 of FIG. 5. In some embodiments, the metal or dummy contact layers 502 may have been previously formed, and the metal or dummy contact layers 502 will be the material of the bottom stack on which an SDI layers are formed. A dummy contact layer is a place holder or sacrificial layer that may be removed at a later stage of a process and replaced with other material to form a metal contact layer and the like. As the material of the bottom stacks 304 on which the SDI layer is to be formed may have been previously formed, the formation of contacts and the like is not required for the method 200 and is therefore optional. The heights 504 of the openings 402 are much greater than the widths 506 of the openings 402. In some embodiments, the method 200 may be used with high aspect ratios (height-to-width) of greater than approximately 15. In some embodiments, the method 200 may be used for aspect ratios of approximately 20 to approximately 30.

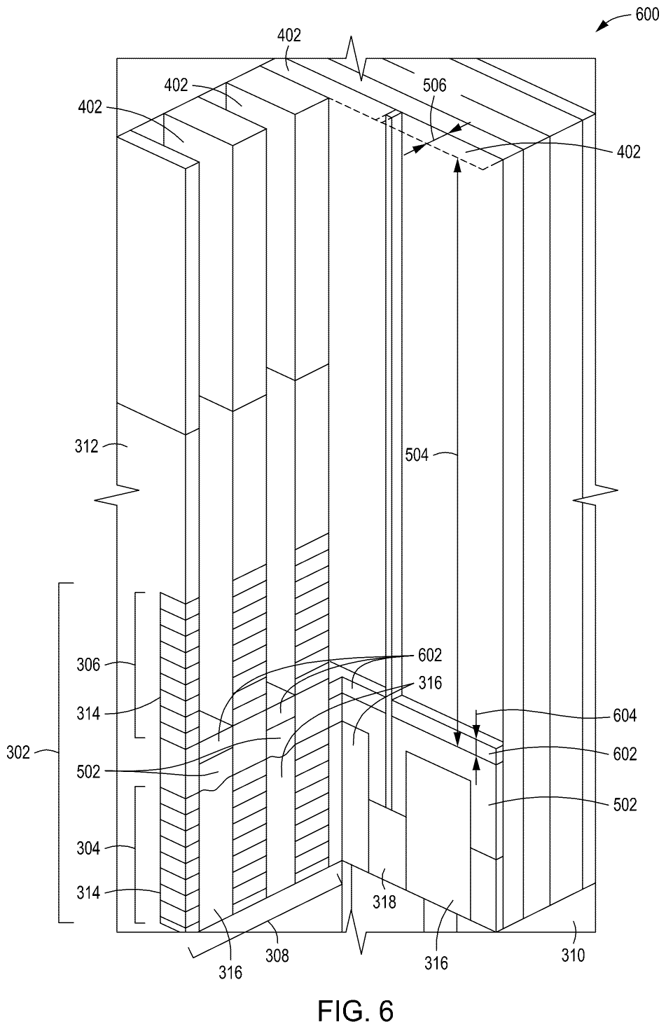

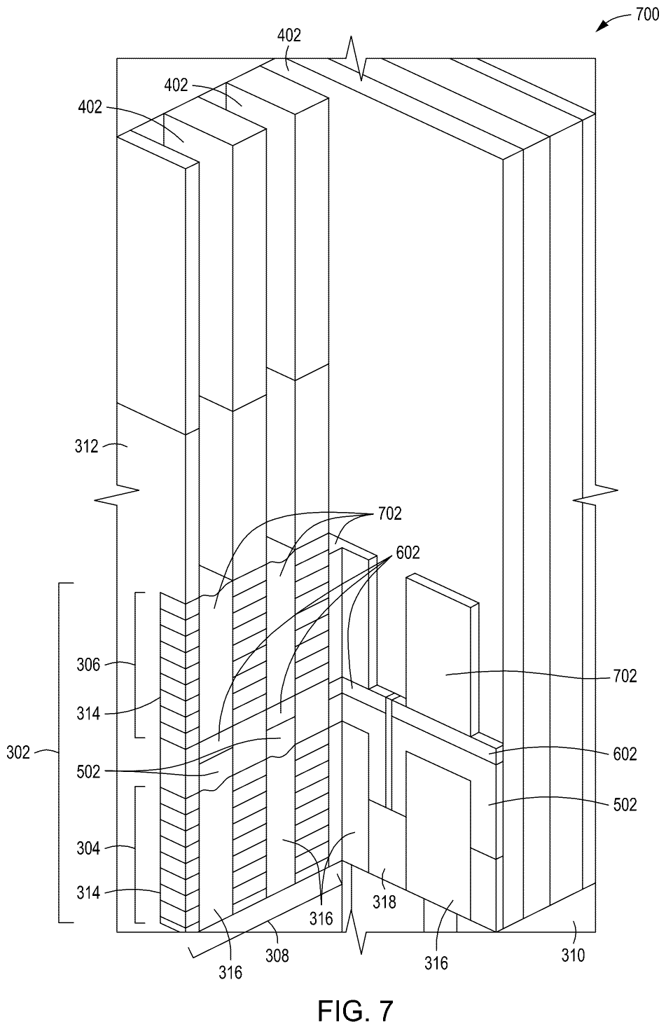

In block 206, source-drain isolation (SDI) layers 602 are formed on the material of the bottom stack such as, for example, the metal or dummy contact layers 502 as depicted in a view 600 of FIG. 6. In some embodiments, the thickness 604 or height of the SDI layers 602 may be approximately 5 nm to approximately 50 nm. The SDI layers 602 are positioned in the CFET structure to electrically isolate the first source-drains 316 of the bottom stacks 304 from the second source-drains 702 (see, FIG. 7) of the top stacks 306. The SDI layers 602 may be formed in situ in a single chamber that performs deposition and etching of the SDI material. In some embodiments, the SDI layers 602 may be formed of silicon dioxide material, silicon nitride material, silicon oxynitride material, silicon oxycarbide material, and/or aluminum oxide material and/or other oxide materials and nitride materials and the like. The method 200 has the benefit of being a shorter process for SDI layer formation than traditional processes using gapfill, CMP, and etch-back processes to attempt to form the SDI layer. The present methods can also achieve the target SDI layer height, irrespective of incoming structure variations, to maintain isolation between the top stacks and the bottom stacks of the CFET structures.

In some embodiments, the bottom-up fill process includes depositing of the SDI material and etching of the SDI material to achieve formation of the SDI layers 602. The deposition portion of the bottom-up fill process may use a plasma enhanced chemical vapor deposition (PECVD) process and/or a plasma enhanced atomic level deposition (PEALD) process. The PECVD deposition process is preferred as deposition rates are higher than with PEALD depositions. However, PECVD deposition results in overhangs at the mouths of the openings 402 and requires etching periodically to prevent closure of the openings 402. PEALD deposition processes and numbers of cycles can be adjusted to avoid the overhangs at the mouths of the openings 402. The etching portion of the bottom-up fill process may use chlorine-based gases and/or fluorine-based gases to etch deposited SDI material from the mouths and sidewalls of the openings 402 while preserving depositions at the bottoms of the openings 402 which form the SDI layers 602. The etch process is an anisotropic etch process used to remove the buildup (overhangs) at the mouths of the openings 402 that may lead to blockage of the deposition process at the bottom of the openings 402. In some embodiments, the deposition and etching processes may be performed alternately for a given number of cycles to complete the formation of the SDI layers 602. In some embodiments, multiple deposition cycles may be performed prior to one or more etching cycles and the entire deposition/etching cycle may be repeated in order to complete the formation of the SDI layers 602. In some embodiments, the number of cycles overall and the number of cycles of each deposition and etch process may be adjusted based on the aspect ratios of the openings 402.

By employing a bottom-up fill process, the thickness variation or height variation of the SDI layers 602 may be less than approximately 10% of a target thickness for the SDI layers 602. The tolerance of traditional gapfill and etch-back processes is a percentage of the total depth (height) of the exposed material of the bottom stack such as, for example but not meant to be limiting, the metal or dummy contact layers (approximately 400 nm in some instances) from the top of the gates. In addition, the traditional processes are composed of a gapfill step and recess or etch-back step with both steps having process variation. For example, a nominal SDI layer height variability is 10% of 400 nm=40 nm which is more than the final target SDI layer thickness. In contrast, the tolerance for the bottom-up fill of the present methods is a percentage of the target SDI layer thickness of approximately 5 nm or less. The nominal SDI layer height variability for the present methods is 10% of 5 nm=0.05 nm which is within the expected tolerance for the SDI layer thickness. In addition, assuming a 10% variation for a nominal process target, the expected variance of traditional processes is four times larger than the total height of the SDI layer as almost the entire gapfill in the opening has to be removed to form the SDI layer, leading to a much larger tolerance error for the traditional process as compared to the present methods. Thus, the present methods significantly reduce the variability, number of processes, and cost.

In block 208, second source-drains 702 of the top stacks 306 of the CFET structures 302 are formed on the SDI layers 602 as depicted in a view 700 of FIG. 7. The second source-drains 702 may be formed using an epitaxial deposition process. The SDI layers 602 provide electrical isolation between the first source-drains 316 of the bottom stacks 304 and top stacks 306 of the CFET structures 302 while restricting the epitaxial growth to the top stack source-drains.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

While the foregoing is directed to embodiments of the present principles, other and further embodiments of the principles may be devised without departing from the basic scope thereof.

1. A method for isolating a source-drain of a complementary field-effect-transistor (CFET) structure, comprising:
forming an opening to access a bottom stack of a CFET structure that also includes a top stack positioned vertically over the bottom stack; and
forming a source-drain isolation (SDI) layer on a material of the bottom stack of the CFET structure using a bottom-up fill process that includes depositing of an SDI material and etching of the SDI material to achieve formation of the SDI layer, wherein the SDI layer is positioned to electrically isolate source-drains of the bottom stack from source-drains of the top stack.

2. The method of claim 1, wherein the material of the bottom stack of the CFET structure is a metal contact material or a dummy contact material and wherein the SDI layer is formed on the metal contact material or the dummy contact material.

3. The method of claim 1, wherein the bottom stack is a P-type metal-oxide-semiconductor (MOS) stack and the top stack is an N-type MOS stack or wherein the bottom stack is an N-type MOS stack and the top stack is a P-type MOS stack.

4. The method of claim 1, wherein formation of the SDI layer is accomplished in situ in a chamber that performs deposition and etching of the SDI material.

5. The method of claim 1, wherein the SDI layer is formed using a plasma enhanced chemical vapor deposition (PECVD) process or a plasma enhanced atomic level deposition (PEALD) process.

6. The method of claim 1, wherein the SDI layer is formed of silicon dioxide material, silicon nitride material, silicon oxynitride material, silicon oxycarbide material, or aluminum oxide material.

7. The method of claim 1, wherein a second source-drain of the top stack is formed on the SDI layer using an epitaxial deposition process.

8. The method of claim 1, wherein a thickness variability of the SDI layer is approximately 10% of a target thickness of the SDI layer.

9. The method of claim 1, wherein the opening has a depth of approximately 400 nm.

10. The method of claim 1, wherein a thickness of the SDI layer is approximately 5 nm to approximately 50 nm.

11. The method of claim 1, wherein etching of the SDI material includes using chlorine-based gases or fluorine-based gases to etch deposition material from sidewalls of the opening.

12. The method of claim 1, wherein a number of cycles of depositing SDI material and etching SDI material is adjusted based on an aspect ratio of the opening.

13. The method of claim 1, wherein multiple cycles of depositing SDI material are performed before multiple cycles of etching SDI materials are performed.

14. A method for isolating a source-drain of a complementary field-effect-transistor (CFET) structure, comprising:
forming an opening to access a first source-drain of a bottom stack of a CFET structure that also includes a top stack positioned vertically over the bottom stack;
forming a metal contact layer or a dummy contact layer on the first source-drain of the bottom stack of the CFET structure; and
forming a source-drain isolation (SDI) layer on the metal contact layer or the dummy contact layer using a bottom-up fill process that includes depositing of an SDI material and etching of the SDI material to achieve formation of the SDI layer, wherein the SDI layer electrically isolates source-drains of the bottom stack from source-drains of the top stack, wherein the SDI layer is formed using a plasma enhanced chemical vapor deposition (PECVD) process or a plasma enhanced atomic level deposition (PEALD) process, and wherein formation of the SDI layer is accomplished in situ in a chamber that performs deposition and etching of the SDI material.

15. The method of claim 14, wherein the bottom stack is a P-type metal-oxide-semiconductor (MOS) stack and the top stack is an N-type MOS stack or wherein the bottom stack is an N-type MOS stack and the top stack is a P-type MOS stack.

16. The method of claim 14, wherein the SDI layer is formed of silicon dioxide material, silicon nitride material, silicon oxynitride, silicon oxycarbide, or aluminum oxide.

17. The method of claim 14, wherein a second source-drain of the top stack is formed on the SDI layer using an epitaxial deposition process.

18. The method of claim 14, wherein a thickness variability of the SDI layer is approximately 10% of a target thickness of the SDI layer.

19. The method of claim 14, wherein a thickness of the SDI layer is approximately 5 nm to approximately 50 nm.

20. A non-transitory, computer readable medium having instructions stored thereon that, when executed, cause a method for isolating a source-drain of a complementary field-effect-transistor (CFET) structure to be performed, the method comprising:
forming an opening to access a bottom stack of a CFET structure that also includes a top stack positioned vertically over the bottom stack; and
forming a source-drain isolation (SDI) layer on a material of the bottom stack of the CFET structure using a bottom-up fill process that includes depositing of an SDI material and etching of the SDI material to achieve formation of the SDI layer, wherein the SDI layer is positioned to electrically isolate source-drains of the bottom stack from source-drains of the top stack.
